(19) United States
(12) Patent Application Publication
(10) Pub. No.: US 2026/0260366 A1
(43) Pub. Date: Sep. 3, 2026

(54) REGION-DENSITY BASED MISALIGNMENT INDEX FOR IMAGE ALIGNMENT

(71) Applicant: ASML Netherlands B.V., Veldhoven (NL)

(72) Inventors: Hongquan ZUO, San Jose, CA (US); Lingling PU, San Jose, CA (US); Ming XU, San Jose, CA (US)

(73) Assignee: ASML Netherlands B.V., Veldhoven (NL)

(21) Appl. No.: 18/876,190

(22) PCT Filed: Jul. 27, 2023
(86) PCT No.: PCT/EP2023/070798

§ 371 Date: Dec. 17, 2024

Related U.S. Application Data
(60) Provisional application No. 63/397,201, filed on Aug. 11, 2022.

(51) Int. Cl. G06T 7/33; G06T 7/00

(52) U.S. Cl. CPC G06T 7/337; G06T 7/001; G06T 2207/10061; G06T 2207/30148

(57) ABSTRACT

An improved method and system for image alignment of an inspection image are disclosed. The improved method and system comprises a misalignment index based on applying a density function to both a sample image and a reference image at a region of interest. One or more metrics, such as cross-correlation of the sample and reference images, can be used to derive a region-density based misalignment index from the density-function images. The index can yield a unique alignment solution that is robust to noise and other errors.

### CROSS-REFERENCE FOR RELATED APPLICATIONS

This application claims priority of U.S. application 63/397,201 which was filed on Aug. 11, 2022 and which is incorporated herein in its entirety by reference.

### TECHNICAL FIELD

The embodiments provided herein relate to an image alignment technology, and more particularly misalignment indices for characterizing a misalignment amount of an image feature.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important. Inspection images such as SEM images can be used to identify or classify a defect(s) of the manufactured ICs. To improve defect detection performance, obtaining an accurate alignment between a SEM image and corresponding design layout data is desired.

### SUMMARY

Embodiments of the present disclosure provide a method of image alignment. The method may comprise: acquiring a first density map of an inspection image corresponding to a region of interest using a first density function; acquiring a second density map of a reference image corresponding to the region of interest using a second density function; and aligning the inspection image and the reference image based on the acquired first and second density maps.

Some embodiments of the present disclosure provide a non-transitory computer-readable medium that stores a set of instructions that is executable by at least one processor of an apparatus to cause the apparatus to perform the above method.

Some embodiments of the present disclosure provide a charged particle beam apparatus configured to perform the above method. The charged particle beam apparatus ay comprise: a charged particle beam source configured to generate a beam of primary charged particles; a charged particle optical system configured to direct the beam of primary charged particles at a sample surface to inspect the sample surface; a charged particle detector configured to detect charged particles returned from the sample surface, wherein the charged particle detector comprises a first sensing element and a second sensing element; and a controller comprising one or more processors and configured to cause the charged particle beam apparatus to perform the above method.

Some embodiments of the present disclosure provide a further method of method of image alignment. The method may comprise: acquiring an inspection image corresponding to a region of interest of a sample; acquiring a reference image corresponding to the region of interest of the sample; acquiring an inspection binary profile of the inspection image using a first binary function; acquiring a reference binary profile of the reference image using a second binary function; acquiring a first density map of the inspection binary profile using a first density function; acquiring a second density map of the reference binary profile using a second density function; and determining an alignment parameter of the inspection image and the reference image based on the acquired first and second density maps.

Some embodiments of the present disclosure provide a non-transitory computer-readable medium that stores a set of instructions that is executable by at least one processor of an apparatus to cause the apparatus to perform the above further method.

Some embodiments of the present disclosure provide a charged particle beam apparatus configured to perform the above method. The charged particle beam apparatus ay comprise: a charged particle beam source configured to generate a beam of primary charged particles; a charged particle optical system configured to direct the beam of primary charged particles at a sample surface to inspect the sample surface; a charged particle detector configured to detect charged particles returned from the sample surface, wherein the charged particle detector comprises a first sensing element and a second sensing element; and a controller comprising one or more processors and configured to cause the charged particle beam apparatus to perform the above further method.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an example charged-particle beam inspection system, consistent with embodiments of the present disclosure.

FIG. 2 is a schematic diagram illustrating an example multi-beam tool that can be a part of the example charged-particle beam inspection system of FIG. 1, consistent with embodiments of the present disclosure.

FIGS. 3A-D illustrate example techniques for generating a misalignment index.

FIG. 4 illustrates an example technique for generating a misalignment index, consistent with embodiments of the present disclosure.

FIG. 5 illustrates an example technique for generating a misalignment index, consistent with embodiments of the present disclosure.

FIGS. 6A-B illustrate example technique for generating a misalignment index, consistent with embodiments of the present disclosure.

FIG. 7 illustrates misalignment index performance, consistent with embodiments of the present disclosure.

FIG. 8 is a process flowchart representing an exemplary method for generating a misalignment index, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (SCPM). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

As the physical sizes of IC components continue to shrink, accuracy and yield in defect detection become more important. Inspection images such as SEM images can be used to identify or classify a defect(s) of the manufactured ICs. To improve defect detection performance, obtaining an accurate alignment between a SEM image and a corresponding reference image is desired. For example, in die-to-database (D2DB) alignment, the SEM image may be compared to a reference image based on design layout data. In die-to-die (D2D) alignment, a defect-free SEM image may be used as a reference for aligning other SEM images having the same design layout. The difference between a SEM and reference image may be used to calculate a misalignment index.

Some conventional alignment methods rely on comparing the locations of pattern edges to determine a degree of misalignment between the SEM and reference images. These methods may not perform well for complex misalignments, such as a scaling or a deformation of the SEM image relative to a reference image. Further, some mathematical techniques of combining the SEM and reference images, such as cross-correlation, may be sensitive to measurement noise. This can lead to inaccuracies in calculating the misalignment index, such as producing many possible solutions to a single alignment problem.

Embodiments of the present disclosure may provide a misalignment index based on region density of pattern features. A process for calculating the misalignment index may involve transforming a SEM image and reference image using a density function to produce images of pattern features that are weighted more heavily at their centers than at the edges. These transformed region-density based SEM and reference images may then be evaluated using, e.g., the cross-correlation mentioned above, to achieve a misalignment measurement that is robust to measurement noise and yields a single alignment solution. The transformed region-density based SEM and reference images may be used to produce a number of other metrics as well, which may then be combined into a region-density based misalignment index.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

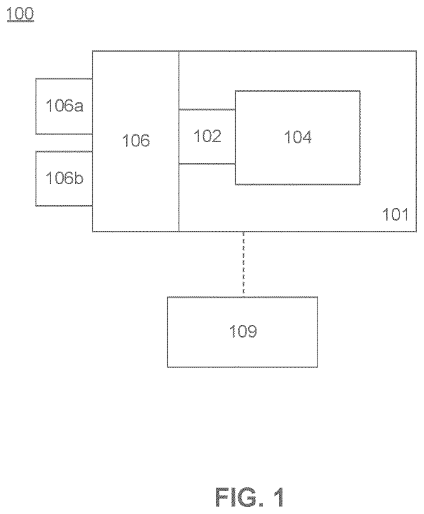

FIG. 1 illustrates an example electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) May transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

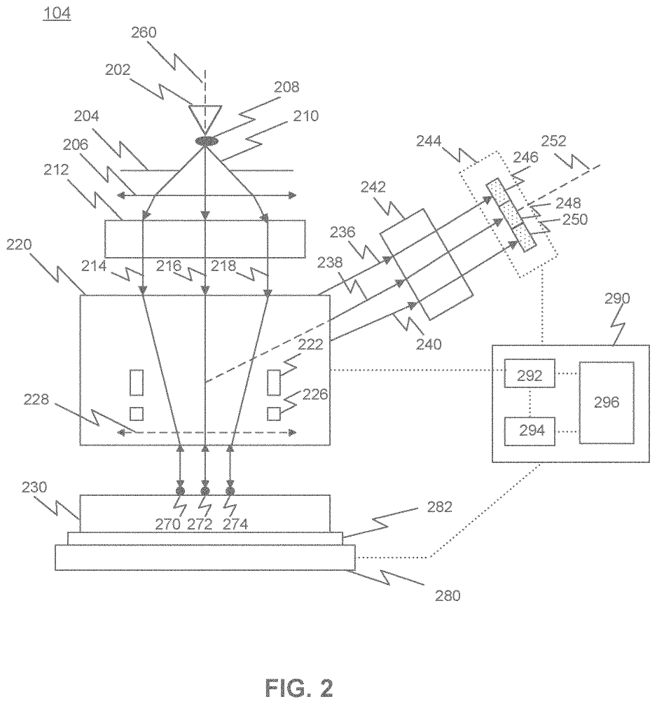

FIG. 2 illustrates a schematic diagram of an example multi-beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, an apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and SEs may be more or fewer (or even the same) than the injected electrons of primary charged-particle beam 210.

In some embodiments, the images may be generated by SEM and used for, e.g., defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SEM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

For ease of explanation without causing ambiguity, electrons are used as examples in some of the descriptions herein. However, it should be noted that any charged particle may be used in any embodiment of this disclosure, not limited to electrons. For instance, a source in a charged-particle beam tool can emit one or more charged particles, such as electrons, protons, ions, muons, or any other particle carrying electric charges. Systems and methods for detection may be used in other imaging systems, such as optical imaging, photon detection, proton detection, x-ray detection, ion detection, or the like. Photon detection may comprise light in the infrared, visible, UV, DUV, EUV, x-ray, or any other wavelength range. Therefore, while detectors in the present disclosure may be disclosed with respect to electron detection, some embodiments of the present disclosure may be directed to detecting other charged particles or photons using other detection systems.

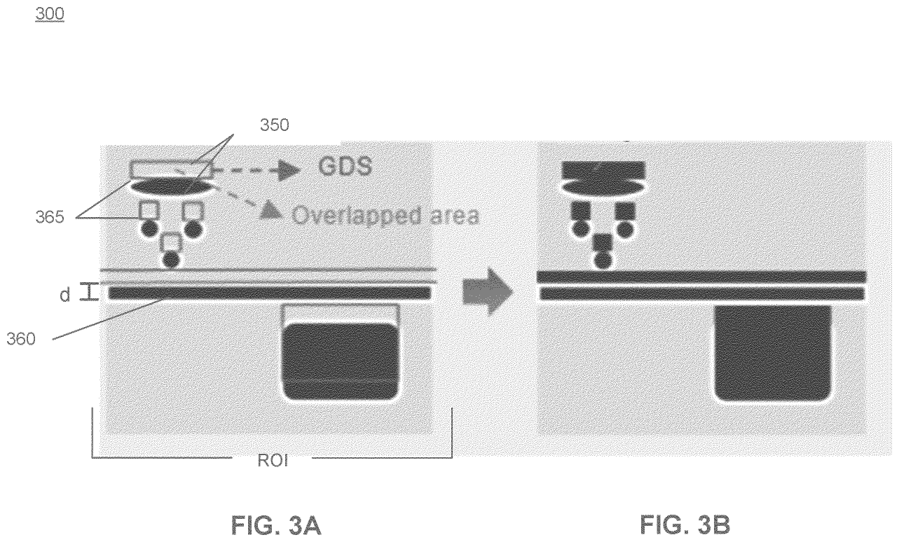

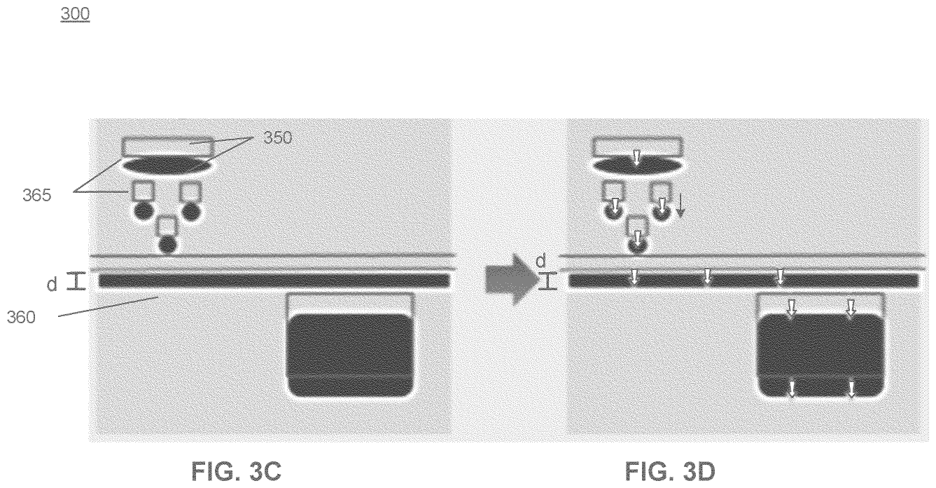

FIGS. 3A-D illustrate misalignment indices 300 according to a comparative embodiment. The misalignment index of FIGS. 3A-B is based on gray-level subtraction, while the index of FIGS. 3C-D is based on a shift amount of a pattern edge feature.

In FIG. 3A, a reference image 350 is overlapped with a SEM image 360 in a region of interest ROI on a sample surface. The sample may be, e.g., a semiconductor wafer. The reference image may be a template, such as a D2DB reference, e.g., a pattern design layout such as a Graphic Database System (GDS) or other file. The methods of FIGS. 3A-D may not be well-suited to D2D methods using a defect-free SEM image as the reference image. As seen in FIG. 3A, reference image 350 is represented by a set of empty polygons that correspond to pattern features 365 of SEM image 360, shifted by a displacement d. To gauge misalignment in the method of FIG. 3A, the area of reference image 350 is subtracted from the gray level value of SEM image 360 as seen in FIG. 3B. Patterns in the reference image that do not align with patterns in the SEM image will leave a dark region in the gray level after subtraction. The subtraction may be used to calculate a misalignment index that takes a normalized range of values from 0 to 1, with 0 representing the best possible alignment value and 1 representing the worst possible alignment value. The SEM and reference images may be aligned based on the misalignment index.

In FIG. 3C, a misalignment index is calculated by determining the displacement d of an edge feature in reference image 350 from its corresponding edge feature in SEM image 360. As illustrated by the arrows in FIG. 3D, multiple displacement measurements may be taken as an average, weighted average, or other combination. As above, the displacement may be used to calculate a misalignment index that takes a normalized range of values from 0 to 1, with 0 representing perfect alignment and 1 representing complete misalignment of pattern features.

Both the subtraction and displacement methods discussed above suffer from several drawbacks. They rely on the characteristics of the pattern feature edges to determine misalignment more than the center regions of pattern features, which renders them difficult to use with low-quality images and are less robust to noise. They are not well-suited to scaling and deformation errors. They are also relatively insensitive to fine misalignments that are becoming less negligible as device features continue to shrink. Additionally, they may not be compatible with D2D reference images.

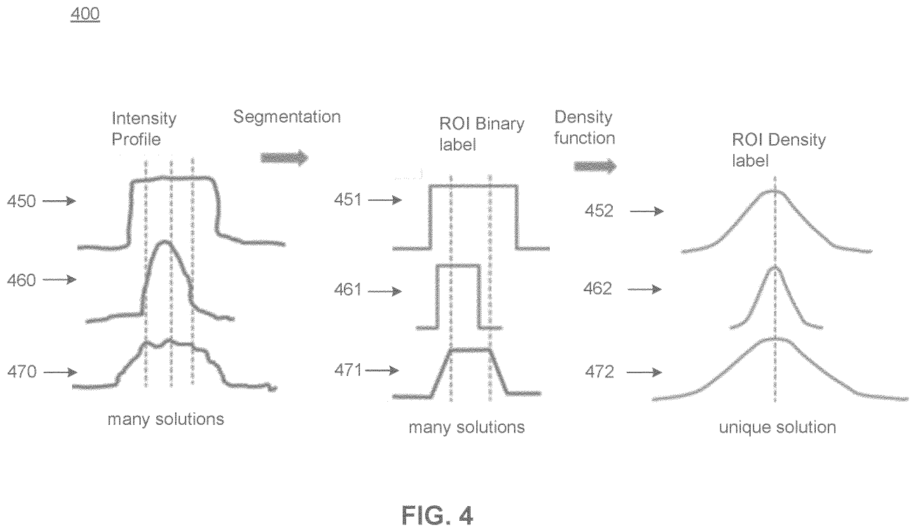

FIG. 4 illustrates a system 400 for region-density based misalignment measurement, consistent with embodiments of the present disclosure. The computations and other operations associated with deriving the misalignment measurement may be performed in a controller, e.g., controller 109 in FIG. 1. The left, center and right columns each show a cross-sectional intensity profiles under three different states for a reference image 450, an inspection image 460 (generated by SEM or other imaging), and a cross-correlation 470 (such as a normalized cross-correlation), of the reference and inspection images. In a cross-correlation algorithm, an alignment that maximizes cross-correlation between an inspection image and a reference image can be outputted as an alignment result. The three states may be, e.g., an intensity profile, a binary transformation profile, and a density transformation profile.

The reference image may be, e.g., a template such as a D2DB reference image. For instance, in some embodiments, a reference image can be a layout file for a wafer design corresponding to the inspection image. The layout file can be a golden image or in a GDS format, Graphic Database System II (GDS II) format, an Open Artwork System Interchange Standard (OASIS) format, a Caltech Intermediate Format (CIF), etc. The wafer design may include patterns or structures for inclusion on the wafer. The patterns or structures can be mask patterns used to transfer features from the photolithography masks or reticles to a wafer. In some embodiments, a layout in GDS or OASIS format, among others, may comprise feature information stored in a binary file format representing planar geometric shapes, text, and other information related to the wafer design. In some embodiments, a reference image can be an image rendered from the layout file. In some embodiments, a GDS image can be rendered to generate an image similar to an inspection image before applying an alignment algorithm, such as an intensity profile reference image 450. Alternatively, intensity profile reference image 450 may be a substantially defect-free inspection image selected as the reference image in a D2D method. In the illustrated example, the intensity profile of reference image 450 may be of the D2D type, as the illustrated intensity profile of reference image 450 includes fluctuations and other irregularities that may not be present in a binary profile. Due to fluctuations in the intensity profiles of reference image 450 and inspection image 460, cross-correlation 470 may have several distinct peaks that could give a false measure of the ideal alignment position between the reference and inspection images. Three such peaks are illustrated by vertical dashed lines in the left column of FIG. 4.

To overcome these fluctuations, the intensity profiles of reference image 450 and inspection image 460 may be binarized, such as by applying a binary transformation, to yield binary reference image 451 and binary inspection image 461 as shown in the center column of FIG. 4. Here, a threshold gray level value may be chosen. Points on the profile below the threshold may be labeled as not containing a pattern feature, while points at or above the threshold may be labeled as containing a pattern feature. It should be understood that if intensity profile reference image 450 is derived from a GDS file or other design data, it may already have a binary form. Furthermore, the thresholds applied to the inspection image and reference image may be the same threshold or different thresholds. Likewise, the binary transformation applied to the inspection and reference images may be the same transformation or different transformations. For example, a binary function may be applied to inspection image 460, and a second binary function may applied to reference image 450. In some embodiments, the first and second binary functions may be the same binary function. While this binarizing operation may smooth out intensity fluctuations, the cross-correlation 471 of the two binary images may still yield multiple alignment solutions. In fact, a continuous range of solutions between vertical dashed lines is seen throughout a plateau of binarized cross-correlation 471.

Therefore, a further transformation may be performed on the reference image 451 and inspection image 461 as to yield the density profiles 452 and 462 in the right column of FIG. 4. For example, a density function may be a transformation applied to the binary image profiles 451/461 to compress their spatial information towards central portions of each pattern feature in the ROI. When information in the binary profiles 451 and 461 of reference image 450 and inspection image 460 is compressed toward the central peaks in each pattern feature as seen in density profiles 452 and 462, cross-correlation density profile 472 may yield a single unique alignment solution as illustrated by the single vertical dashed line. For example, each of the density profiles 452 and 462 may comprise a range of density values that generally increases towards a center of each pattern feature. The single unique alignment solution may be based in part on peak density values in the density profile 452 of reference image 450 and peak density values in the density profile 462 of inspection image 460. In some embodiments of the present disclosure, an alignment solution may be based a plurality of density values in the density profiles, with greater weight being given to higher density values. Therefore, the inspection and reference images may be aligned based on the region-density based misalignment index.

Similar to the binary transformations above, the density transformations applied to the inspection and reference images may be the same transformation or different transformations. For example, a first density function may be applied to inspection image 460 (such as by applying the first density function to inspection binary profile 461), and a second density function may applied to reference image 450 (such as by applying the second density function to reference binary profile 451). In some embodiments, the first and second density functions may be the same density function.

The region-density based alignment of FIG. 4 may have several advantages over, e.g., an edge-based alignment process. For example, flat regions of pattern features, e.g. dark holes or bright metal regions, may be more reliable misalignment indicators than edge patterns. The density profiles in FIG. 4 may allow for a robust and automated center-to-center alignment using compressed information from these flat regions. The density profiles 452/462 may be less sensitive to noise than their intensity profile counterparts 450/460 and their binary counterparts 451/461. Yet they may be more sensitive to small misalignment amounts, and to scaling and deformation errors between a reference and inspection image. And as discussed above, the region-density based alignment may provide a single solution per aligned feature.

Cross-correlation density profile 472 of reference image 452 and inspection image 462 may be used to produce a region-density based misalignment index. For example, the misalignment index may take the form:

$$MA Index = 1 - [ x \cdot y / ( \vert x \vert \cdot \vert y \vert ) ] \qquad ( equation 1 )$$

where x represents inspection density profile 462, and y represents reference density profile 452. Cross-correlation density profile 472 may provide an index of misalignment ranging from 0 to 1, with a misalignment index of 0 being the best possible alignment value and a misalignment index of 1 being the worst possible alignment value.

The region-density based misalignment index may be a key performance indicator in charged particle beam inspection processes, such as a inspection using EBI tool 100 of FIG. 1. The region-density based misalignment index may applied in, e.g., various alignment processes, automatic parameter tunning and data filtering, etc.

In some embodiments, the region-density based misalignment index may be based on a single metric such as equation 1 above. However, further metrics may be desired in order to evaluate a score derived using the first metric. Further, in some embodiments, density profiles 452 and 462 may be used to create multiple metrics that are combined in a region-density based misalignment index. In some embodiments, classification techniques may be applied to alignment of inspection and reference images, thus allowing classification metrics, such as max F1 score, to be applied to the alignment problem.

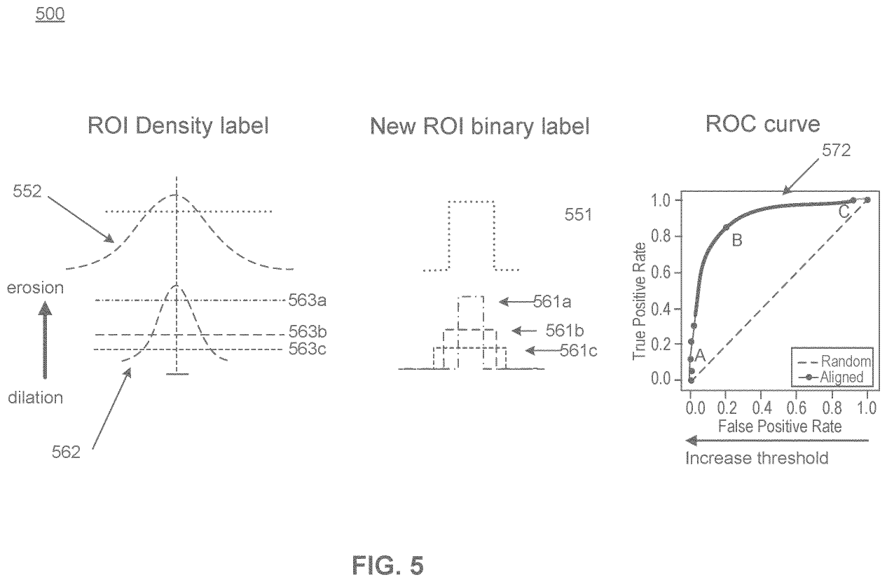

FIG. 5 illustrates a further metric 500 for use in region-density based misalignment measurement, consistent with embodiments of the present disclosure. In FIG. 5, a fixed binarization threshold may be applied to reference density profile 552. Reference density profile 552 may be, e.g., reference density profile 452 of FIG. 4. Using the fixed threshold, a new reference binary profile 551 may be generated from density profile 552. Then a new binary profile 561 may be generated from inspection density profile 562 by selecting a binarization threshold that yields a best fit for reference binary profile 551.

For example, a dilation-erosion operation may be applied to inspection image density profile 562. For example, inspection image density profile 562 may be, e.g., profile 462 of FIG. 4. A range of threshold values may be determined from a maximum erosion (minimum dilation) value a, through an intermediate value b, and to a maximum dilation (minimum erosion) value c. This yields a set of candidate binary inspection profiles, such as binary inspection profiles 561a-c. While only three representative values are depicted in FIG. 5, it should be understood that any number of intervening threshold values may be taken.

The values may be plotted in a receiver operating characteristic (ROC) curve 572. ROC curve 572 may be used to analyze the performance of a classification model. The ROC curve may plot a true positive rate (e.g., the ratio of true positives to the sum of true positives and false negatives), also known as the recall, along the y axis against a false positive rate (e.g., the ratio of false positives to the sum of false positives and true negatives) along the x axis for a range of classification threshold values. A true positive may correspond to a point at which the candidate inspection binary profile 561 correctly predicts that a pattern feature is present in the reference binary profile 551. In other words, a true positive occurs at any point where both the inspection and reference profiles depict a pattern feature. A false positive may correspond to a point at which the candidate inspection binary profile 561 incorrectly predicts that a pattern feature is present in the reference binary profile 551. In other words, a false positive occurs wherever the candidate inspection profile depicts a pattern feature that is not present in the reference profile. Similarly, a true negative may correspond to a point at which the candidate inspection binary profile 561 correctly predicts that a pattern feature is not present in the reference binary profile 551. A false negative may correspond to a point at which the candidate inspection binary profile 561 incorrectly predicts that a pattern feature is not present in the reference binary profile 551.

Inspection profile 561a is considered for illustrative purposes. In the ROC curve 572 of FIG. 5, a low value on the x axis corresponds to a high erosion threshold, such as threshold 563a, which leads to the narrow binary inspection profile 561a. Because every pattern feature point in inspection profile 561a is aligned with a pattern feature point in reference profile 551, every positive is a true positive. However, because candidate inspection profile 561a also fails to identify many actual positives in the reference profile 551, the number of false negatives is also high. Therefore, the true positive rate of profile 561a is low. Further, because there are few or no false positives, the numerator in the false positive rate is low.

An optimal value may correspond to a point that optimizes the true positive and false positive rates. For example, a max F1 score may be used to determine an optimal inspection binary profile 561 for matching with the reference profile 551. The F1 score may be a harmonic mean of the recall (true positive rate) and the precision (i.e., the ratio of true positives to the sum of true and false positives). The F1 score may take values in the range from 0 to 1, wherein 0 represents the poorest classification score and 1 represents the best. Thus the max F1 score measures maximum similarity between an inspection image and its reference at all possible dilation/erosion scales.

In FIG. 5, three F1 scores A, B, and C are plotted along ROC curve 572. The F1 scores A, B and C correspond respectively to binarization thresholds 563a, 563b, and 563c, and to binary inspection profiles 561a, 561b, and 561c. A max F1 score may correspond to, e.g., point B and profile 561b. The F1 score B of profile 561b therefore represents another measure of fitness between an inspection and reference image, and it may be used as a further metric in a region-density based misalignment index. While the max F1 score is discussed as one possible classification metric above, some embodiments of the present disclosure may include other classification metrics, alternatively or in addition to a max F1 score. For example, an area under curve (AUC) of, e.g., the ROC 572 in FIG. 5 may be utilized as a further metric in deriving a region-density based misalignment index.

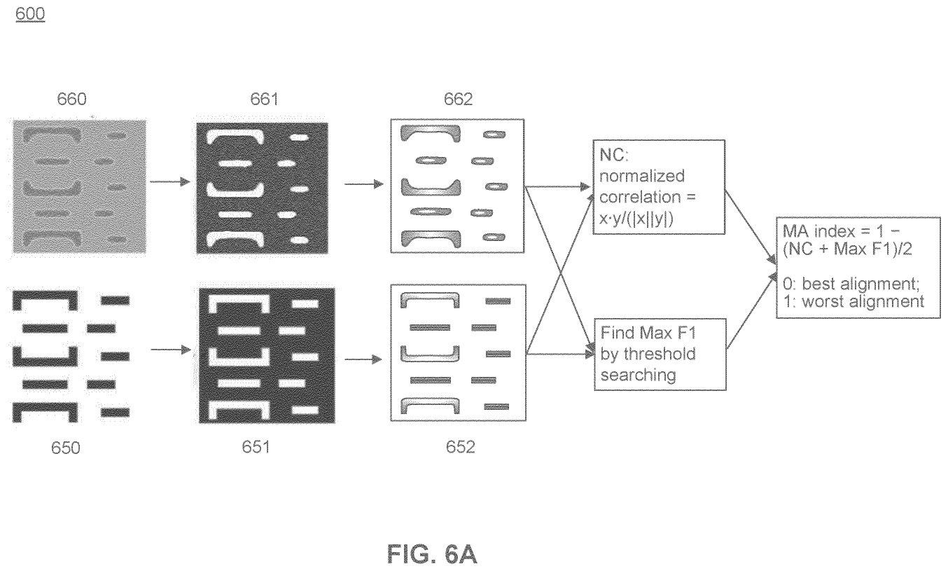

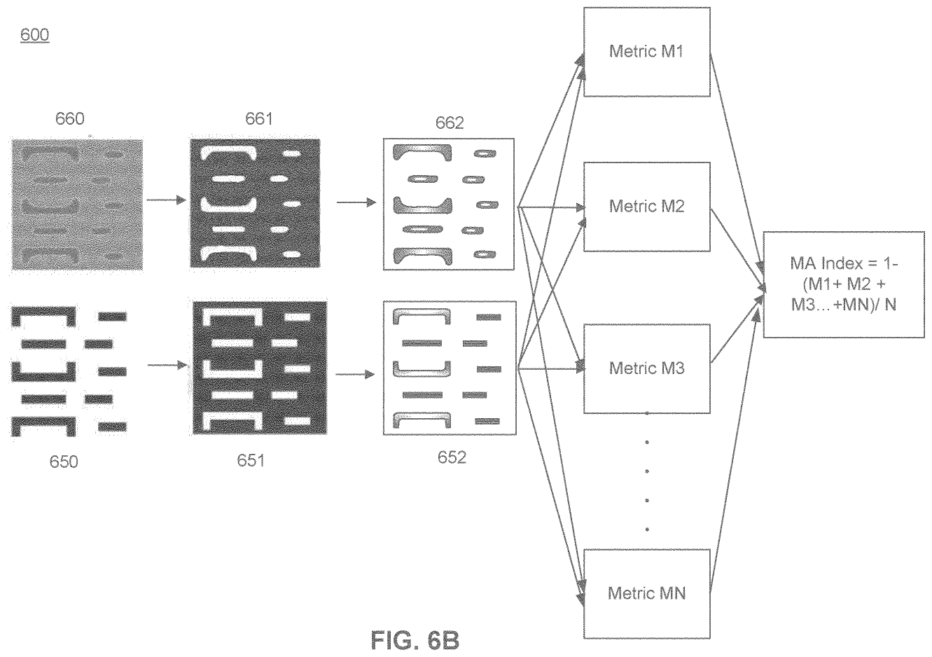

FIGS. 6A-B illustrate region-density based misalignment indices 600 comprising a plurality of metrics, consistent with embodiments of the present disclosure. FIG. 6A shows a plurality of inspection and reference image maps for a ROI. Reference intensity map 650 and inspection intensity map 660 may each be binarized into reference binary map 651 and inspection binary map 661, respectively. For example, a first binary function may be applied to inspection intensity map 660 and a second binary function may be applied to reference intensity map 650. The reference intensity map 650, inspection intensity map 660, reference binary map 651, and inspection binary map 661, may be, e.g., reference intensity profile 450, inspection intensity profile 460, reference binary profile 451, and inspection binary profile 461, respectively, of FIG. 4. Similar to the process discussed with respect to FIG. 4, the binary maps 651/661 may be transformed into region density maps 652/662, such as by applying first and second density functions as discussed above. As discussed above with respect to FIG. 4, the first and second binary functions may be the same as, or different from, each other. Likewise, the first and second density functions may be the same as, or different from, each other.

These region density maps may then be used to derive one or more metrics which may be combined into a region-density based misalignment index. For example, as seen in FIG. 6A, reference region density map 652 and inspection region density map 662 may be combined using normalized cross-correlation NC as discussed with respect to FIG. 4. The normalized cross-correlation NC may take the form of the bracketed term in equation 1, [x·y/(|x|·|y|)], where x represents inspection density map 662, and y represents reference density map 652. This normalized score will take values between 0 and 1, where 0 represents no correlation and 1 represents perfect correlation.

In a parallel process, the same maps 652/662 may be used to derive a max F1 score as discussed above with respect to FIG. 5. For example, the max F1 score may be determined by comparing a reference binary map at a fixed threshold (such as reference binary map 651) to a plurality of new inspection binary maps. The new inspection binary maps may be generated by applying a dilation-erosion operation to inspection density map 662 to generate a plurality of binarization thresholds. The plurality of new binary maps may be analyzed according to classification techniques as discussed above with respect to FIG. 5, for example to determine a max F1 score of the plurality of inspection binary maps. This max F1 score may also take a value between 0 and 1, wherein 0 represents the poorest classification score and 1 represents the best.

The result of the two scores may be combined, e.g., in a weighted average to yield a region-density based misalignment index. For example, as seen in FIG. 6A, the weights are equal and the combination is a simple average, giving a misalignment index of:

$$MA Index = 1 - [ ( NC + Max F 1 ) / 2 ] \qquad ( equation 2 )$$

where NC is a normalized cross-correlation value and Max F1 is a max F1 score as discussed above. Here, the terms are averaged and subtracted from 1, such that the 0 corresponds to the best alignment and 1 corresponds to the worst. However, the misalignment index need not be presented in this form. Further, the two components of the misalignment index need not be weighted equally. In general, in some embodiments of the present disclosure, two metrics may be combined in which a first metric is assigned a coefficient C₁ and a second metric is assigned a coefficient C₂, wherein (C₁+C₂)=1. It should be further understood that a misalignment index is not limited to a range of 0 to 1, nor to a combination of only two metrics.

For example, FIG. 6B illustrates a more general case of the arrangement of FIG. 6A. Here, reference region density map 652 and inspection region density map 662 may be combined into a plurality of metrics M1 through MN. The metrics may be combined into a misalignment index and averaged as shown. Alternatively, the metrics may be combined in another way. For example, the metrics may be assigned weights C₁ through C_{N} where (C₁+C₂+C₁ . . . +C_{N})=1. In general, the metrics may be combined in any suitable manner. The choice of metrics and the weight distribution may be determined using a machine learning or other data-driven approach. In some embodiments of the present disclosure, massive training datasets may be used to train a misalignment index model for use in specific applications.

A region-density based misalignment index may be used to align an inspection and reference image as discussed above with respect to FIG. 4. For example, each of the density maps 652 and 662 may comprise a range of density values that generally increases towards a center of each pattern feature. A unique alignment solution may be based in part on peak density values in the density map 652 of reference image map 650 and peak density values in the density map 662 of inspection image map 660. In some embodiments of the present disclosure, an alignment solution may be based a plurality of density values in the density profiles, with greater weight being given to higher density values. Therefore, the inspection and reference images may be aligned based on the region-density based misalignment index.

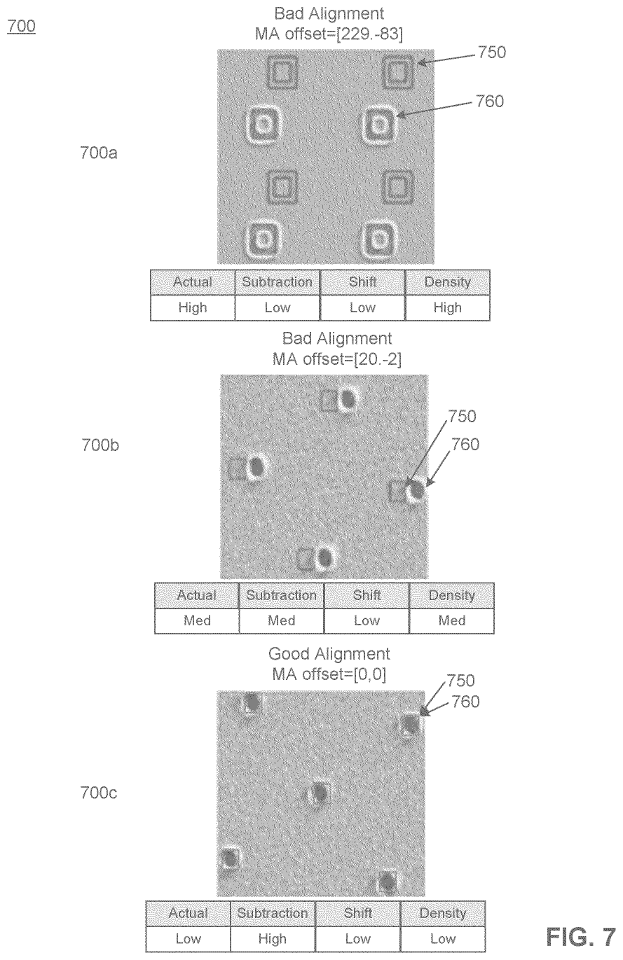

FIG. 7 illustrates a comparison 700 between misalignment indices of conventional systems and a region-density based misalignment index consistent with embodiments of the present disclosure. In FIG. 7, three different alignment scenarios 700a-700c are presented. Alignment scenario 700a represents a poor alignment between a reference image 750 and an inspection image 760. In 700a, an accurate misalignment index may produce a high index value. The middle view 700b represents a less poor alignment between a reference image 750 and an inspection image 760. In 700b, an accurate misalignment index may produce a medium index value. Finally, the bottom view 700c represents a good alignment between a reference image 750 and an inspection image 760. In 700c, an accurate misalignment index may produce a low index value.

First, a comparative misalignment index based on subtraction method, as discussed above with respect to FIGS. 3A-B, is considered. In FIG. 7, the subtraction method is seen trending in the wrong direction across all three alignments 700a-c, such that it produces a low index value for high misalignments and vice versa. For example, in the worst alignment scenario 700a, the subtraction misalignment index produces a low misalignment value when the actual misalignment is high. Similarly, in the best alignment scenario 700c, the subtraction misalignment index produces a high misalignment value when the actual misalignment is low. While the subtraction misalignment index appears to yield a decent measurement for the middle scenario 700b, the subtraction misalignment index is not consistent across all scenarios 700a-c and therefore cannot be relied upon to produce an accurate index value.

Next, a comparative misalignment index based on a shift method, as discussed above with respect to FIGS. 3C-D, is considered. In FIG. 7, the shift method is insensitive to changes in actual misalignment, yielding a low index value in each scenario. For example, in the worst alignment scenario 700a, the shift misalignment index produces a low misalignment value when the actual misalignment is high. In the middle alignment scenario 700b, the shift misalignment index again produces a low misalignment value where the actual misalignment is a medium value. While the shift misalignment index appears to yield a decent measurement for the best alignment scenario 700c, the shift misalignment index consistently produces a low value across all scenarios 700a-c. Thus the shift misalignment index, like the subtraction misalignment index, cannot be relied upon to produce an accurate index value.

Finally, a region-density based misalignment index, consistent with embodiments of the present disclosure, is considered. Here, the region-density based misalignment index tracks accurately along with the actual misalignment at each of the high, medium and low misalignment scenarios 700a-c. For example, in the worst alignment scenario 700a, the region-density based misalignment index produces a high misalignment value and the actual misalignment is also high. In the middle alignment scenario 700b, the region-density based misalignment index produces a medium misalignment value and the actual misalignment is also a medium value. In the best alignment scenario 700c, the region-density based misalignment index produces a low misalignment value and the actual misalignment is also low. The region-density based misalignment index exhibits superior performance on misalignment robustness and sensitivity over the two comparative misalignment indices.

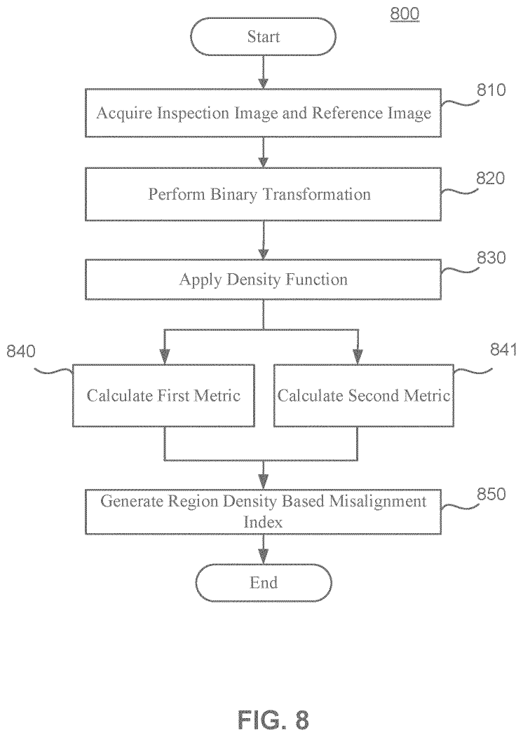

FIG. 8 illustrates a method 800 for generating a region-density based misalignment index, consistent with embodiments of the present disclosure. The method may be performed by, e.g., a one or more processors coupled to a memory. The method may be performed by, e.g., a controller of an imaging or inspection device such as, e.g., controller 109 of FIG. 1 or image processing system 290 of FIG. 2. An inspection image to be used in method 800 may be generated by an inspection device, such as EBI system 100 of FIG. 1 or electron beam tool 104 of FIGS. 1-2. Alternatively, an inspection image may be generated by other imaging systems, such as optical imaging, photon detection, proton detection, x-ray detection, ion detection, or the like. Photon detection may comprise light in the infrared, visible, UV, DUV, EUV, x-ray, or any other wavelength ranges.

At step 810, an inspection image and a reference image are acquired for a region of interest ROI. The inspection image may be generated by, e.g., SEM or other imaging. The reference image may be generated from, e.g., a design layout file or a representative inspection image that has been selected as a reference. The image may represent, e.g., an intensity profile or intensity map, such as a gray level map of the inspection and reference images. The ROI may be, e.g., a region under inspection on a sample surface, such as semiconductor wafer.

At step 820, a binarization process is performed on the inspection and reference images. The binarization process may transform an image having a plurality of intensity values or gray level values into a binary image having two values. A first value may represent an area having a pattern feature, and a second value may represent an area having no pattern features. For example, the binary images may comprise binary profiles or binary maps as seen at FIGS. 4-6B. In some embodiments, a reference image may be acquired in binary form and need no further binarization at step 820.

At step 830, a density function is applied to the inspection and reference images. The density function may be a single density function, or may comprise a first density function applied to the inspection image (such as by applying a first density function to the binary inspection image derived at step 820), and a second density function applied to the reference image (such as by applying a second density function to the binary reference image derived at step 820). The density function may compress information of the inspection and reference images from peripheral or edge regions of pattern features into more central regions of the pattern features. The density function may be used to produce density images representing the inspection and reference images. For example, the density images may comprise density profiles or density maps as seen at FIGS. 4-6B.

At step 840, a first metric is calculated based on the inspection density image and the reference density image. The first metric may comprise, e.g., a normalized cross-correlation, max F1 value, AUC, or other classification or alignment evaluation metrics. In some embodiments, an optional further step 841 may comprise calculating a second such metric. In some embodiments, more than two metrics may be calculated.

At step 850, a region-density based misalignment index is generated using the one or more metrics produced at steps 840 or 841. The region-density based misalignment index may comprise a weighted average or another other suitable combination of metrics to yield the misalignment index. The choice of metrics and the weight distribution may be determined using a machine learning or other data-driven approach. In some embodiments of the present disclosure, massive training datasets may be used to train a misalignment index model for use in specific applications.

The method may comprise any of the steps illustrated with respect to, e.g., FIGS. 1, 2, and 4-7 above, as well as those discussed with respect to FIG. 8 and further below. The misalignment index generated by the method 800 may be applied to, e.g., a charged particle beam process carried out by EBI system 100 of FIG. 1 or electron beam tool 104 of FIGS. 1-2.

A non-transitory computer readable medium may be provided that stores instructions for a processor of a controller (e.g., controller 109 of FIG. 1) to carry out, among other things, image inspection, image acquisition, stage positioning, beam focusing, electric field adjustment, beam bending, condenser lens adjusting, activating charged-particle source, beam deflecting, as well as method 800 or other methods comprising process steps discussed with respect to FIGS. 1, 2 and 4-7. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and

Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method of image alignment, comprising:
   acquiring a first density map of an inspection image corresponding to a region of interest using a first density function;
   acquiring a second density map of a reference image corresponding to the region of interest using a second density function; and
   aligning the inspection image and the reference image based on the acquired first and second density maps.
2. The method of clause 1, wherein the first density function and the second density function are the same.
3. The method of clause 1, wherein the first density function and the second density function are different from each other.
4. The method of clause 1, wherein:
   acquiring the first density map comprises acquiring a first range of density values including a first density value;
   acquiring the second density map comprises acquiring a second range of density values including a second density value; and
   aligning the inspection image and the reference image based on the acquired first and second density values; wherein the first density value is a first peak density value within the first range of density values and the second density value is a second peak density value within the second range of values.
5. The method of clause 1, further comprising:
   acquiring a first binary transformation of the inspection image using a first binary function;
   acquiring a second binary transformation of the reference image using a second binary function.
6. The method of clause 5, wherein:
   acquiring the first density map using the first density function comprises applying the first density function to the first binary transformation; and
   acquiring the second density map using the second density function comprises applying the second density function to the second binary transformation.
7. The method of clause 5, wherein the first binary function and the second binary function are the same.
8. The method of clause 5, wherein the first binary function and the second binary function are different from each other
9. The method of clause 1, further comprising:
   determining a region-density based misalignment index based on the acquired first and second density maps;
   wherein aligning the inspection image and the reference image based on the acquired first and second density maps comprises aligning the inspection image and the reference image based on the region-density based misalignment index.
10. The method of clause 9, further comprising:
   determining a first metric based on the first on the acquired first and second density maps;
   wherein the region-density based misalignment index is determined based on the first metric.
11. The method of clause 10, further comprising:
   determining a second metric based on the first on the acquired first and second density maps, the second metric being different from the first metric;
   wherein the region-density based misalignment index is determined based on a combination of the first metric and the second metric.
12. The method of clause 10, wherein the first metric is based on one of a cross-correlation, a normalized cross-correlation, an F1 score, and an area under curve (AUC) of a receiver operating characteristic (ROC) curve.
13. The method of clause 1, further comprising:
   determining an overlay error based on the acquired first and second density maps.
14. The method of any of clauses 1-13, wherein the inspection image is a charged particle beam image.
15. The method of clause 14, wherein the charged particle beam image is a SEM image.
16. The method of any of clauses 1-15, wherein the reference image is based on one of a design layout file and a reference SEM image.
17. A non-transitory computer-readable medium that stores a set of instructions that is executable by at least one processor of an apparatus to cause the apparatus to perform a method comprising:
   acquiring a first density map of an inspection image corresponding to a region of interest using a first density function;
   acquiring a second density map of a reference image corresponding to the region of interest using a second density function; and
   aligning the inspection image and the reference image based on the acquired first and second density maps.
18. The non-transitory computer-readable medium of clause 17, wherein the first density function and the second density function are the same.
19. The non-transitory computer-readable medium of clause 17, wherein the first density function and the second density function are different from each other.
20. The non-transitory computer-readable medium of clause 17, wherein:
   acquiring the first density map comprises acquiring a first range of density values including a first density value;
   acquiring the second density map comprises acquiring a second range of density values including a second density value; and
   the first density value is a first peak density value within the first range of values and the second density value is a second peak density value within the second range of values.
21. The non-transitory computer-readable medium of clause 17, wherein the set of instructions that is executable by the at least one processor of the apparatus causes the apparatus to further perform:
   acquiring a first binary transformation of the inspection image using a first binary function;
   acquiring a second binary transformation of the reference image using a second binary function.
22. The non-transitory computer-readable medium of clause 21, wherein:
   acquiring the first density map using the first density function comprises applying the first density function to the first binary transformation; and
   acquiring the second density map using the second density function comprises applying the second density function to the second binary transformation.
23. The non-transitory computer-readable medium of clause 21, wherein the first binary function and the second binary function are the same.
24. The non-transitory computer-readable medium of clause 21, wherein the first binary function and the second binary function are different from each other
25. The non-transitory computer-readable medium of clause 17, wherein the set of instructions that is executable by the at least one processor of the apparatus causes the apparatus to further perform:
   determining a region-density based misalignment index based on the acquired first and second density maps;
   wherein aligning the inspection image and the reference image based on the acquired first and second density maps comprises aligning the inspection image and the reference image based on the region-density based misalignment index.
26. The non-transitory computer-readable medium of clause 25, wherein the set of instructions that is executable by the at least one processor of the apparatus causes the apparatus to further perform:
   determining a first metric based on the first on the acquired first and second density maps;
   wherein the region-density based misalignment index is determined based on the first metric.
27. The non-transitory computer-readable medium of clause 26, wherein the set of instructions that is executable by the at least one processor of the apparatus causes the apparatus to further perform:
   determining a second metric based on the first on the acquired first and second density maps, the second metric being different from the first metric;
   wherein the region-density based misalignment index is determined based on a combination of the first metric and the second metric.
28. The non-transitory computer-readable medium of clause 26, wherein the first metric is based on one of a cross-correlation, a normalized cross-correlation, an F1 score, and an area under curve (AUC) of a receiver operating characteristic (ROC) curve.
29. The non-transitory computer-readable medium of any of clauses 17-28, wherein the inspection image is a charged particle beam image.
30. The non-transitory computer-readable medium of clause 29, wherein the charged particle beam image is a SEM image.
31. The non-transitory computer-readable medium of any of clauses 17-30, wherein the reference image is based on one of a design layout file and a reference SEM image.
32. A charged particle beam apparatus, comprising:
   a charged particle beam source configured to generate a beam of primary charged particles;
   an optical system configured to direct the beam of primary charged particles at a sample surface to inspect the sample surface;
   a charged particle detector configured to detect charged particles returned from the sample surface;
   a controller comprising one or more processors and configured to cause the charged particle beam apparatus to perform:
   acquiring a first density map of an inspection image corresponding to a region of interest using a first density function;
   acquiring a second density map of a reference image corresponding to the region of interest using a second density function; and
   aligning the inspection image and the reference image based on the acquired first and second density maps.
33. The charged particle beam apparatus of clause 32, wherein the first density function and the second density function are the same.
34. The charged particle beam apparatus of clause 32, wherein the first density function and the second density function are different from each other.
35. The charged particle beam apparatus of clause 32, wherein:
   acquiring the first density map comprises acquiring a first range of density values including a first density value;
   acquiring the second density map comprises acquiring a second range of density values including a second density value; and
   the first density value is a first peak density value within the first range of values and the second density value is a second peak density value within the second range of values.
36. The charged particle beam apparatus of clause 32, wherein the controller is further configured to cause the charged particle beam apparatus to perform:
   acquiring a first binary transformation of the inspection image using a first binary function;
   acquiring a second binary transformation of the reference image using a second binary function.
37. The charged particle beam apparatus of clause 36, wherein:
   acquiring the first density map using the first density function comprises applying the first density function to the first binary transformation; and
   acquiring the second density map using the second density function comprises applying the second density function to the second binary transformation.
38. The charged particle beam apparatus of clause 36, wherein the first binary function and the second binary function are the same.
39. The charged particle beam apparatus of clause 36, wherein the first binary function and the second binary function are different from each other
40. The charged particle beam apparatus of clause 32, wherein the controller is further configured to cause the charged particle beam apparatus to perform:
   determining a region-density based misalignment index based on the acquired first and second density maps;
   wherein aligning the inspection image and the reference image based on the acquired first and second density maps comprises aligning the inspection image and the reference image based on the region-density based misalignment index.
41. The charged particle beam apparatus of clause 40, wherein the controller is further configured to cause the charged particle beam apparatus to perform:
   determining a first metric based on the first on the acquired first and second density maps;
   wherein the region-density based misalignment index is determined based on the first metric.
42. The charged particle beam apparatus of clause 41, wherein the controller is further configured to cause the charged particle beam apparatus to perform:
   determining a second metric based on the first on the acquired first and second density maps, the second metric being different from the first metric;
   wherein the region-density based misalignment index is determined based on a combination of the first metric and the second metric.
43. The charged particle beam apparatus of clause 41, wherein the first metric is based on one of a cross-correlation, a normalized cross-correlation, an F1 score, and an area under curve (AUC) of a receiver operating characteristic (ROC) curve.
44. The charged particle beam apparatus of any of clauses 32-43, wherein the inspection image is a charged particle beam image.
45. The charged particle beam apparatus of clause 44, wherein the charged particle beam image is a SEM image.
46. The charged particle beam apparatus of any of clauses 32-45, wherein the reference image is based on one of a design layout file and a reference SEM image.
47. A method of image alignment, comprising:
   acquiring an inspection image corresponding to a region of interest of a sample;
   acquiring a reference image corresponding to the region of interest of the sample;
   acquiring an inspection binary profile of the inspection image using a first binary function;
   acquiring a reference binary profile of the reference image using a second binary function;
   acquiring a first density map of the inspection binary profile using a first density function;
   acquiring a second density map of the reference binary profile using a second density function; and
   determining an alignment parameter of the inspection image and the reference image based on the acquired first and second density maps.
48. A non-transitory computer-readable medium that stores a set of instructions that is executable by at least one processor of an apparatus to cause the apparatus to perform a method comprising:
   acquiring an inspection image corresponding to a region of interest of a sample;
   acquiring a reference image corresponding to the region of interest of the sample;
   acquiring an inspection binary profile of the inspection image using a first binary function;
   acquiring a reference binary profile of the reference image using a second binary function;
   acquiring a first density map of the inspection binary profile using a first density function;
   acquiring a second density map of the reference binary profile using a second density function; and
   determining an alignment parameter of the inspection image and the reference image based on the acquired first and second density maps.
49. A charged particle beam apparatus, comprising:
   a charged particle beam source configured to generate a beam of primary charged particles;
   an optical system configured to direct the beam of primary charged particles at a sample surface to inspect the sample surface;
   a charged particle detector configured to detect charged particles returned from the sample surface;
   a controller comprising one or more processors and configured to cause the charged particle beam apparatus to perform:
   acquiring an inspection image corresponding to a region of interest of a sample;
   acquiring a reference image corresponding to the region of interest of the sample;
   acquiring an inspection binary profile of the inspection image using a first binary function;
   acquiring a reference binary profile of the reference image using a second binary function;
   acquiring a first density map of the inspection binary profile using a first density function;
   acquiring a second density map of the reference binary profile using a second density function; and
   determining an alignment parameter of the inspection image and the reference image based on the acquired first and second density maps.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A non-transitory computer-readable medium that stores a set of instructions that is executable by at least one processor of an apparatus to cause the apparatus to perform a method comprising:
acquiring a first density map of an inspection image corresponding to a region of interest using a first density function;
acquiring a second density map of a reference image corresponding to the region of interest using a second density function; and
aligning the inspection image and the reference image based on the acquired first and second density maps.

2. The non-transitory computer-readable medium of claim 1, wherein the first density function and the second density function are the same.

3. The non-transitory computer-readable medium of claim 1, wherein the first density function and the second density function are different from each other.

4. The non-transitory computer-readable medium of claim 1, wherein:
acquiring the first density map comprises acquiring a first range of density values including a first density value;
acquiring the second density map comprises acquiring a second range of density values including a second density value; and
the first density value is a first peak density value within the first range of values and the second density value is a second peak density value within the second range of values.

5. The non-transitory computer-readable medium of claim 1, wherein the set of instructions that is executable by the at least one processor of the apparatus causes the apparatus to further perform:
acquiring a first binary transformation of the inspection image using a first binary function;
acquiring a second binary transformation of the reference image using a second binary function.

6. The non-transitory computer-readable medium of claim 5, wherein:
acquiring the first density map using the first density function comprises applying the first density function to the first binary transformation; and
acquiring the second density map using the second density function comprises applying the second density function to the second binary transformation.

7. The non-transitory computer-readable medium of claim 5, wherein the first binary function and the second binary function are the same.

8. The non-transitory computer-readable medium of claim 5, wherein the first binary function and the second binary function are different from each other

9. The non-transitory computer-readable medium of claim 1, wherein the set of instructions that is executable by the at least one processor of the apparatus causes the apparatus to further perform:
determining a region-density based misalignment index based on the acquired first and second density maps;
wherein aligning the inspection image and the reference image based on the acquired first and second density maps comprises aligning the inspection image and the reference image based on the region-density based misalignment index.

10. The non-transitory computer-readable medium of claim 9, wherein the set of instructions that is executable by the at least one processor of the apparatus causes the apparatus to further perform:
determining a first metric based on the first on the acquired first and second density maps;
wherein the region-density based misalignment index is determined based on the first metric.

11. The non-transitory computer-readable medium of claim 10, wherein the set of instructions that is executable by the at least one processor of the apparatus causes the apparatus to further perform:
determining a second metric based on the first on the acquired first and second density maps, the second metric being different from the first metric;
wherein the region-density based misalignment index is determined based on a combination of the first metric and the second metric.

12. The non-transitory computer-readable medium of claim 10, wherein the first metric is based on one of a cross-correlation, a normalized cross-correlation, an F1 score, and an area under curve (AUC) of a receiver operating characteristic (ROC) curve.

13. The non-transitory computer-readable medium of claim 1, wherein the inspection image is a charged particle beam image.

14. The non-transitory computer-readable medium of claim 13, wherein the charged particle beam image is a SEM image.

15. The non-transitory computer-readable medium of claim 1, wherein the reference image is based on one of a design layout file and a reference SEM image.
